(19) United States
(12) Patent Application Publication
(10) Pub. No.: US 2007/0089836 A1
(43) Pub. Date: Apr. 26, 2007

(54) Semiconductor process chamber

(75) Inventors: Craig Metzner, Fremont, CA (US); Per-Ove Hansson, San Jose, CA (US)

Correspondence Address: MOSER IP LAW GROUP / APPLIED MATERIALS, INC., 1040 BROAD STREET, 2ND FLOOR, SHREWSBURY, NJ, 07702, US

(73) Assignee: Applied Materials, Inc.

(21) Appl. No.: 11/258,345

(22) Filed: Oct. 24, 2005

(51) Int. Cl. H01L 21/306; C23C 16/00

(52) U.S. Cl. 156/345.51; 156/914; 118/728

(57) ABSTRACT

A process kit for a semiconductor process chamber is provided herein. In one embodiment, a process kit for a semiconductor processing chamber, includes one or more components fabricated from a metal-free sintered silicon carbide material. The process kit comprises at least one of a substrate support, a pre-heat ring, lift pins, and substrate support pins. In another embodiment, a semiconductor process chamber is provided, having a chamber body and a substrate support disposed in the chamber body. The substrate support is fabricated from metal-free sintered silicon carbide. Optionally, the process chamber may include a process kit having at least one component fabricated from a metal-free sintered silicon carbide.

### BACKGROUND OF THE INVENTION

1. Field of the Invention

Embodiments of the present invention generally relate to apparatus for fabricating integrated circuits. More specifically, the present invention relates to process chambers for fabricating thin films on substrates.

2. Description of the Related Art

Thin films are generally fabricated in process chambers selectively adapted for performing various deposition, etch, and thermal processes, among other processes, upon substrates, such as silicon (Si) wafers, gallium arsenide (GaAs) wafers, glass or sapphire substrates, and the like. These processes often use or develop process environments (e.g., environments containing aggressive chemistries, plasmas, by-products, etc.) that may gradually erode, consume, or contaminate various exposed components of the processing chambers, such as substrate supports, substrate lift pins, process kits (e.g., heat rings, deposition rings, retaining rings, and the like), process shields (heat shields, plasma shields, and the like), and the like.

As such, these components are periodically inspected, refurbished (e.g., cleaned), and/or replaced—typically, on a set maintenance schedule (e.g., after a predetermined number of manufacturing cycles). To increase overall lifetime and maintenance intervals, and thereby increase process equipment uptime and reduce the cost of production, these components are generally fabricated from materials resistant to specific processing environments present in process chamber.

One such process-resistant material is silicon carbide (SiC). As an example, most process chambers for epitaxial deposition of silicon films utilize components fabricated from graphite having a silicon carbide coating. The silicon carbide coating is typically formed via chemical vapor deposition (CVD) upon the graphite components. However, silicon carbide deposited via CVD typically has a relatively low thickness and durability, which may wear sooner and is more susceptible to damage. The rapid deterioration of the CVD coating leads to more frequent refurbishment and/or replacement of coated components. In addition, thicker CVD coatings tend to have a higher intrinsic stress, leading to cracking, peeling, and/or delamination, and the like. Also, the thicker coated CVD parts can exaggerate thermal effects of a non-uniform CVD coating, which can lead to non-uniform process results.

Silicon carbide components may also be formed from sintered and hot pressed silicon carbide having metallic binders, such as aluminum (Al), boron (B), beryllium (Be), and the like. However, the metallic binders added to the silicon carbide during sintering are typically released into the process chamber during high-temperature processes, such as epitaxial silicon deposition processes, chemical vapor deposition (CVD) processes, rapid thermal processes (RTPs), and the like. The released metals from the binders causes metal contamination of the thin films, substrate, and/or interior of the process chamber during processing, and can damage the devices on the wafer.

Therefore, there is a need in the art for improved semiconductor substrate processing reactors.

### SUMMARY OF THE INVENTION

A process kit for a semiconductor process chamber is provided herein. In one embodiment, a process kit for a semiconductor processing chamber, includes one or more components fabricated from a metal-free sintered silicon carbide material. The process kit comprises at least one of a substrate support, a pre-heat ring, a lift pin, and a substrate support pin.

In another embodiment, a semiconductor process chamber is provided, having a chamber body and a substrate support disposed in the chamber body. The substrate support is fabricated from metal-free sintered silicon carbide.

In another embodiment, a semiconductor process chamber includes a chamber body; a substrate support disposed in the chamber body, wherein the substrate support is fabricated from sintered silicon carbide using non-metallic sintering agents; and one or more of a pre-heat ring, a lift pin, and a substrate support pin, wherein at least one of the pre-heat ring, the lift pin, and the substrate support pin is fabricated from a solid silicon carbide (SiC) material sintered using non-metallic sintering agents.

### BRIEF DESCRIPTION OF THE DRAWINGS

The teachings of the present invention will become apparent by considering the following detailed description in conjunction with the accompanying drawings, in which:

FIG. 1 depicts a schematic, cross-sectional view of a semiconductor substrate process chamber in accordance with one embodiment of the present invention;

FIG. 2 depicts a schematic, cross-sectional view of a substrate support of the kind that may be used in the process chamber of FIG. 1;

FIG. 3 depicts a schematic, cross-sectional view of a lift pin of the kind that may be used in the process chamber of FIG. 1;

FIG. 4 depicts a schematic, cross-sectional view of a pre-heat ring of the kind that may be used in the process chamber of FIG. 1; and

FIG. 5 depicts a schematic, cross-sectional view of a substrate support pin of the kind that may be used in the process chamber of FIG. 1.

Where possible, identical reference numerals are used herein to designate identical elements that are common to the figures. The images in the drawings are simplified for illustrative purposes and are not depicted to scale.

The appended drawings illustrate exemplary embodiments of the invention and, as such, should not be considered as limiting the scope of the invention, which may admit to other equally effective embodiments.

### DETAILED DESCRIPTION

The present invention provides a process chamber suitable for fabricating and/or treating thin films on substrates such as semiconductor wafers, glass or sapphire substrates, and the like (collectively and generically referred to herein as a “substrate”). The process chamber contains at least one component that is fabricated from a metal-free sintered silicon carbide. In one embodiment, the invention may be used in the fabrication of integrated semiconductor devices and circuits.

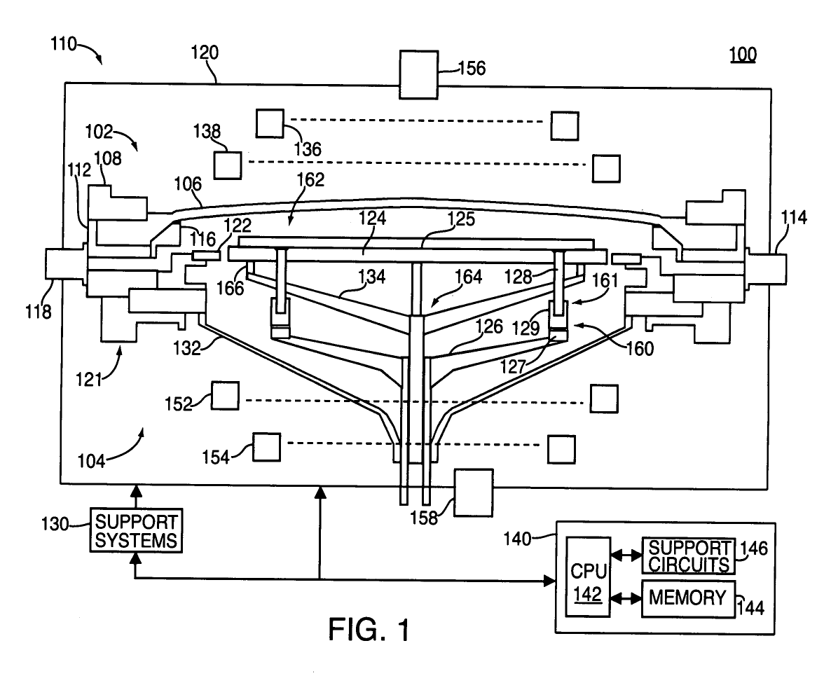

FIG. 1 is a schematic, cross-sectional view of a semiconductor substrate process chamber 100 in accordance with one embodiment of the present invention. In the depicted embodiment, the process chamber 100 is adapted for performing epitaxial silicon deposition processes. One such suitable reactor is the RP Epi reactor, available from Applied Materials, Inc. of Santa Clara, Calif.

In alternate embodiments, the process chamber 100 may be adapted for performing at least one of deposition processes, etch processes, plasma enhanced deposition and/or etch processes, and thermal processes, among other processes performed in the manufacture of integrated semiconductor devices and circuits. Specifically, such processes may include, but are not limited to, rapid thermal processes (RTPs), chemical vapor deposition (CVD) processes, annealing processes, and the like.

The process chamber 100 illustratively comprises a chamber body 110, support systems 130, and a controller 140. The chamber body 110 generally includes an upper portion 102, a lower portion 104, and an enclosure 120.

The upper portion 102 is disposed on the lower portion 104 and includes a lid 106, a clamp ring 108, a liner 116, a baseplate 112, one or more upper lamps 136 and one or more lower lamps 138, and an upper pyrometer 156. In one embodiment, the lid 106 has a dome-like form factor, however, lids having other form factors (e.g., flat or reverse-curve lids) are also contemplated. The lower portion 104 is coupled to a process gas intake port 114 and an exhaust port 118 and comprises a baseplate assembly 121, a lower dome 132, a substrate support 124, a pre-heat ring 122, a substrate lift assembly 160, a substrate support assembly 164, one or more upper lamps 152 and one or more lower lamps 154, and a lower pyrometer 158. Although the term “ring” is used to describe certain components of the process chamber, such as the pre-heat ring 122, it is contemplated that the shape of these components need not be circular and may include any shape, including but not limited to, rectangles, polygons, ovals, and the like.

During processing, a substrate 125 is disposed on the substrate support 124. The lamps 136, 138, 152, and 154 are sources of infrared (IR) radiation (i.e., heat) and, in operation, generate a pre-determined temperature distribution across the substrate 125. In one embodiment, the lid 106, the clamp ring 116, and the lower dome 132 are formed from quartz; however, other IR-transparent and process compatible materials may also be used to form these components.

The substrate support assembly 164 generally includes a support bracket 134 having a plurality of support pins 166 coupled to the substrate support 124. The substrate lift assembly 160 comprises a substrate lift shaft 126 and a plurality of lift pin modules 161 selectively resting on respective pads 127 of the substrate lift shaft 126. In one embodiment, a lift pin module 161 comprises an optional base 129 and a lift pin 128 coupled to the base 129. Alternatively, a bottom portion of the lift pin 128 may rest directly on the pads 1.27. In addition, other mechanisms for raising and lowering the lift pins 128 may be utilized. An upper portion of the lift pin 128 is movably disposed through a first opening 162 in the substrate support 124. In operation, the substrate lift shaft 126 is moved to engage the lift pins 128. When engaged, the lift pins 128 may raise the substrate 125 above the substrate support 124 or lower the substrate 125 onto the substrate support 124.

The support systems 130 include components used to execute and monitor pre-determined processes (e.g., growing epitaxial silicon films) in the process chamber 100. Such components generally include various sub-systems. (e.g., gas panel(s), gas distribution conduits, vacuum and exhaust sub-systems, and the like) and devices (e.g., power supplies, process control instruments, and the like) of the process chamber 100. These components are well known to those skilled in the art and are omitted from the drawings for clarity.

The controller 140 generally comprises a central processing unit (CPU) 142, a memory 144, and support circuits 146 and is coupled to and controls the process chamber 100 and support systems 130, directly (as shown in FIG. 1) or, alternatively, via computers (or controllers) associated with the process chamber and/or the support systems.

Certain components in process chambers similar to the one as described above are typically periodically replaced in order to minimize the effects of wear of these components. Such replaceable components are typically referred to as a process kit. In one embodiment, the process kit of the process chamber 100 may comprise one or more of the substrate support 124, the pre-heat ring 122, the lift pins 128, or the substrate support pins 166.

In one embodiment, one or more of the components of the process kit (e.g., one or more of the substrate support 124, pre-heat ring 122, lift pins 128, or support pins 166), may be partially or completely fabricated from a metal-free sintered silicon carbide. Typically, at least a portion of the component that is exposed to the process chamber or the process environment inside the process chamber is fabricated from the metal-free sintered silicon carbide. The metal-free sintered silicon carbide may be formed using non-metallic sintering agents, such as phenol resins having silicon-based additives. In one embodiment, the metal-free sintered silicon carbide may be PUREBETAE® silicon carbide, available from Bridgestone Corporation, Advanced Materials Division, located in Tokyo, Japan.

Optionally, other process chamber components may also be fabricated from this material. Specifically, the components disposed in the processing volume of a process chamber, outside the processing volume, and/or outside the process chamber may be fabricated from the metal-free sintered silicon carbide material, including at least portions of an electrostatic chuck, shields (e.g., substrate, sputtering target, and/or chamber wall shields, and the like), a showerhead, a receptacle of a substrate robot, and other like components that may come into contact with the process environment and/or the substrate being processed.

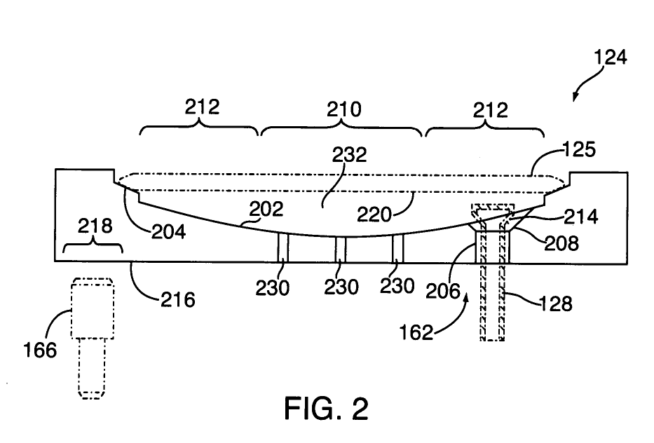

Advantages of the metal-free sintered silicon carbide include high thermal conductivity, excellent machinability and hardness, chemical purity and inertness in most processing environments, and compatibility with low-contamination film processing. In the exemplary process chamber 100 depicted in FIG. 1, components fabricated from metal-free sintered silicon carbide facilitate providing a high uniformity temperature distribution across the substrate 125 and low-contamination deposition of epitaxial silicon films. These and other advantages of using process kits having components fabricated from metal-free sintered SiC are discussed below with reference to FIGS. 2-5.

FIG. 2 depicts a schematic, cross-sectional view of one embodiment of a substrate support 124 described with respect to FIG. 1 fabricated from metal-free sintered silicon carbide. The metal-free sintered silicon carbide has a greater thermal conductivity than CVD silicon carbide-coated graphite, thereby facilitating improved heat transfer from the substrate support 124 to the substrate 125. The high thermal conductivity of the metal-free sintered silicon carbide substrate support 124 facilitates the fabrication and use of thinner substrate supports 124, as compared to CVD SiC coated substrate supports, while maintaining or improving temperature uniformity across the substrate. The thinner substrate supports 124 advantageously allow for faster heatup and cooldown times which improve process throughput, and also facilitates temperature uniformity and control. For example, the thickness of the substrate support 124 may be controlled such that certain regions of the substrate are selectively heated at relatively greater or lesser rates to better tune the process. In one embodiment, the substrate support 124 has a thickness in the range of about 0.04-0.25 inches. In another embodiment, the substrate support 124 has a thickness in the range of about 0.07-0.12 inches.

In the depicted embodiment, the substrate support 124 has a dish-like form factor and includes a concave upper surface 202, a substrate seating surface 204, a first plurality of openings 162 (one first opening 162 shown in FIG. 2), and a backside surface 216. The concave upper surface 202 has a central region 210 and a peripheral region 212. Optionally, one or more openings 230 (three openings 230 shown in FIG. 2), may be formed through the substrate support 124 between the concave upper surface 202 and the backside surface 216. The openings 230 may be of any size and shape (e.g., round holes, elongated holes or slots, rectangular or other polygonal openings, and the like) and may be arranged randomly or in any geometric pattern. In one embodiment, between about 2-700 openings 230 are formed through the substrate support 124. In another embodiment, between about 50-500 openings 230 are formed through the substrate support 124. The size and number of the openings 230 generally provide a percent open area in the substrate support 124 of about 5-15 percent. In one embodiment, the openings 230 comprise round holes having a diameter of between about 0.02-0.375 inches. In one embodiment, the openings 230 are radially arranged on the substrate support 124. The openings 230 facilitate the reduction of autodoping, backside haze, and/or halo defects on the substrate 125. Furthermore, the openings 230 are completely formed within the metal-free sintered silicon carbide, thereby avoiding the difficulty of depositing silicon carbide on the sidewalls of holes formed in graphite substrates, upon which it is typically difficult to obtain a satisfactory CVD coating.

Optionally, a thickness profile of the substrate support 124 may be selectively varied to control the uniformity of films deposited on the substrate 125. Areas where the substrate support 124 is thicker will cause the substrate 125 to be hotter, and areas where the substrate support 124 is thinner will cause the substrate 125 to be cooler. The selective control of the relative temperature of different areas of the substrate 125 facilitates control of the formation of films on the substrate 125. Alternatively or in combination, the size of a gap 222 between the substrate 125 and the substrate support 124 can be selectively formed to control the uniformity of films deposited on the substrate 125. For example, the gap 222 may be wider (to reduce heat transfer) in areas where it is desired that the substrate 125 be cooler. In one embodiment, the a profile of the gap 222 is varied by up to about 0.012 inches. The thickness profile of the substrate support 124 and/or the gap 222 may be controlled by the shape of the concave upper surface 202 and/or by selective contouring of the backside surface 216 of the substrate support 124.

Fabricating the substrate support 124 (or other components of the process kit) from metal-free sintered silicon carbide further advantageously allows for greater control over polishing the component to further control the rate of heat transfer through the particular component as compared to CVD-coated parts. It is difficult to polish thin CVD silicon carbide coatings, which tend to be inadvertently partially or completely removed by the polishing process, thereby undesirably exposing the underlying graphite or other base material. In addition, the polishing process may result in extremely thin regions in the silicon carbide coating which may be etched through or worn in a short period of time.

In one embodiment, regions of the concave upper surface 202 may be selectively machined to control the heat transfer rate across varying regions of the substrate support 124. For example, the peripheral region 212 may be machined to a roughness that facilitates reduction of heat transfer to a peripheral portion of the substrate 125 disposed above the peripheral region 212. The selective reduction of heat transfer facilitates control of the temperature distribution on the substrate 125. Alternatively or in combination, the central region 210 may be machined to a roughness less than that of the peripheral region 212, to increase the heat transfer, or the relative heat transfer, to a central portion of the substrate 125 disposed above the central region 210. The selective control of heat transfer to the substrate 125, and thereby control of the substrate temperature distribution, facilitates control of the thickness profile of films being deposited upon the substrate 125.

For example, the substrate support 124 may be selectively machined to provide a roughness of the concave upper surface 202 in a central region 210 that is pre-determinedly less than a roughness in a peripheral region 212. In one embodiment, the roughness of the concave upper surface 202 in the central region 210 is about 0.2-8 μm and the roughness of the concave upper surface 202 in the peripheral region 212 is about 8-20 μm. In one embodiment, the roughness of the concave upper surface 202 in the central region 210 is about 4 μm and the roughness of the concave upper surface 202 in the peripheral region 212 is about 16 μm.

The substrate seating surface 204 provides a region where a backside surface 220 of the substrate 125 contacts, and rests upon, the substrate support 124. The substrate seating surface 204 may be polished or machined smooth. The smooth substrate seating surface 204 facilitates forming a tight seal with the backside surface 220 of the substrate 125 during processing, thereby preventing deposition gases from contacting the backside surface 220 of the substrate 125.

For example, the substrate seating surface 204 of the substrate support 124 may be selectively machined to a pre-determined roughness. In one embodiment, the roughness of the substrate seating surface 204 is about 0.2-10 μm. In one embodiment, the roughness of the substrate seating surface 204 is about 6 μm.

In addition, the purity of the metal-free sintered silicon carbide advantageously provides a chemically-inert contact to the backside surface 220 of the substrate 125, thereby reducing autodoping defects of the substrate 125.

The first plurality of openings 162 house the lift pins 128 (one lift pin 128 is shown in phantom lines) and are typically configured to match the profile of the lift pins 128, for example, to prevent the lift pins 128 from falling through the first openings 162 and to prevent and/or reduce leakage of gases into or from the region between the substrate 125 and the concave surface 202 of the substrate support 124. In one embodiment, the first openings 162 include a cylindrical surface 206 through which the lift pins 128 may move, and a conical surface 208 that matches the profile of a seating surface 214 of the lift pins 128, thereby facilitating the formation of a tight seal with the seating surface 214 of the lift pin 128.

For example, the conical surface 208 of the substrate support 124 may be machined or polished to a pre-determined roughness to enhance the seal formed between the conical surface 208 and the seating surface 214 of the lift pin 128. In one embodiment, the roughness of the conical surface 208 is about 0.2-5 μm. In one embodiment, the roughness of the conical surface 208 is about 0.2 μm.

The backside surface 216 includes regions 218 adapted for positioning the substrate support 124 on the substrate support pins 166 (one region 219 and one pin 166 is shown in FIG. 2). The backside surface 216 may also polished. In one embodiment, at least regions 218 of the backside surface 216 are polished to a roughness of about 0.2-10 μm. In one embodiment, regions 218 of the backside surface 216 are polished to a roughness of about 6 μm.

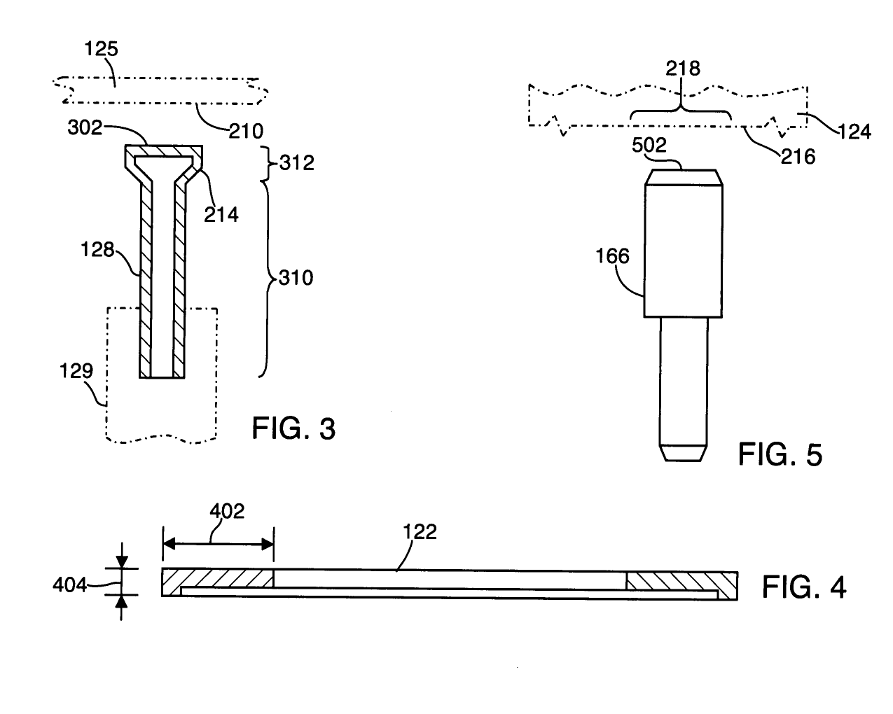

FIG. 3 depicts a schematic, cross-sectional view of one embodiment of the lift pin 128 depicted in FIG. 1 fabricated from metal-free sintered silicon carbide. In one embodiment, the lift pin 128 comprises a stem portion 310 coupled to the base 129 (shown in phantom lines) and an upper portion 312. It is contemplated that other lift pin designs, for example, without a separate base 129 may be utilized as well. The stem portion 310 passes through the opening 206 in the substrate support 124 (depicted in FIG. 2). The upper portion 312 includes a seating surface 214 and a flat top surface 302.

As discussed above with reference to FIG. 2, when retracted, the seating surface 214 of the lift pin 128 rests upon the concave upper surface 202 of the substrate support 124 (see FIG. 2). To further facilitate forming a tight seal therebetween, the seating surface 214 of the lift pin 128 may be machined or polished to a pre-determined roughness. In one embodiment, the seating surface 214 is polished to a roughness of about 0.2-5 μm. In one embodiment, the seating surface 214 is polished to a roughness of about 0.02 μm.

When the lift pins 128 are extended, e.g., when raising or lowering the substrate 125, the flat top surface 302 engages the backside surface 220 of the substrate 125 (shown in phantom lines). The flat top surface 302 of the lift pin 128 may be machined or polished to a pre-determined roughness to facilitate smooth contact with the substrate 125. In one embodiment, the flat top surface 302 is polished to a roughness of about 0.2-10 μm. In one embodiment, the flat top surface 302 is polished to a roughness of about 8 μm.

In addition, as discussed above, the purity of the metal-free sintered silicon carbide advantageously provides a chemically-inert contact to the backside surface 220 of the substrate 125, thereby reducing contamination of the substrate 125 due to impurities present in sintered silicon carbide having metallic binders.

FIG. 4 depicts a schematic, cross-sectional view of one embodiment of the pre-heat ring 122 described above with respect to FIG. 1. The pre-heat ring 122 may be fabricated from the metal-free sintered silicon carbide material as discussed above. A width 402 and thickness 404 of the pre-heat ring 122 are selected to provide a pre-determined mass for absorbing heat from the lamps 136, 138, 152, and 154 (shown in FIG. 1) to preheat the gas introduced into the process chamber body 110 during processing. As discussed above, the metal-free sintered silicon carbide has a greater thermal conductivity than CVD silicon carbide coated graphite, thereby facilitating improved heat transfer from the lamps to the process gases.

FIG. 5 depicts a schematic, cross-sectional view of one embodiment of the support pin 166 described above with respect to FIG. 1. The support pin 166 may be fabricated from the metal-free sintered silicon carbide. The support pin 166 has a top surface 502 that contacts and supports the substrate support 124 along region 218 of the backside surface 216. The top surface 502 of the support pin 166 forms a particle-free contact with the region 218 of the backside surface 216. In one embodiment, the top surface 502 is machined or polished to a roughness of about 1-16 μm. In one embodiment, the top surface 502 is machined or polished to a roughness of about 5 μm. Optionally, the support pin 166 may be only partially fabricated from the metal-free sintered silicon carbide, e.g., only in an upper portion of the support pin 166 proximate the backside surface 216.

Although the above description describes specific components as being fabricated from the metal-free sintered silicon carbide, it is contemplated that other components of the processing chamber that contact or are disposed proximate the substrate may be fabricated from the metal-free sintered silicon carbide as well. In addition, the invention may be practiced by those skilled in the art in other processing reactors by utilizing the teachings disclosed herein without departing from the spirit of the invention. Although the foregoing discussion refers to fabrication of semiconductor devices, fabrication of the other devices and structures used in integrated circuits can also benefit from the invention.

While the foregoing is directed to embodiments of the present invention, other and further embodiments of the invention may be devised without departing from the basic scope thereof, and the scope thereof is determined by the claims that follow.

1. A process kit for a semiconductor processing chamber, comprising:
one or more components fabricated from a metal-free sintered silicon carbide material.

2. The process kit of claim 1, wherein the components comprise at least one of a substrate support, a pre-heat ring, a lift pin, and a substrate support pin.

3. The process kit of claim 1, wherein the components comprise a pre-heat ring.

4. A semiconductor processing chamber, comprising:
a chamber body; and
a substrate support disposed in the chamber body, wherein the substrate support is fabricated from metal-free sintered silicon carbide.

5. The chamber of claim 4, wherein the reactor is adapted for performing at least one of a deposition process, an etch process, a plasma enhanced deposition and/or etch process, and a thermal process.

6. The chamber of claim 4, wherein the reactor is adapted for performing chemical vapor deposition processes.

7. The chamber of claim 4, wherein the reactor is adapted for performing rapid thermal processes.

8. The chamber of claim 4, wherein the reactor is adapted for performing epitaxial silicon deposition processes.

9. The chamber of claim 4, wherein the substrate support further comprises:
a concave upper surface machined to achieve a pre-determined temperature distribution on a surface of a substrate disposed thereon.

10. The chamber of claim 9, wherein the concave upper surface has a first roughness in a central region of the concave upper surface and a second roughness in a peripheral region of the concave upper surface.

11. The chamber of claim 10, wherein the first roughness is less than the second roughness.

12. The chamber of claim 10, wherein the first roughness is about 0.2 to 8 μm, and the second roughness is about 8 to 20 μm.

13. The chamber of claim 4, wherein the substrate support further comprises:
a substrate seating surface adapted for contacting a peripheral edge of a substrate disposed thereupon.

14. The chamber of claim 13, wherein the substrate seating surface is polished to roughness of about 0.2 to 10 μm.

15. The chamber of claim 4, wherein the substrate support further comprises:
a plurality of openings adapted for housing a plurality of substrate lift pins, wherein lift pin engaging surfaces of the plurality of openings are polished to roughness of about 0.2 to 5 μm.

16. The chamber of claim 4, further comprising:
a plurality of lift pins fabricated from metal-free sintered silicon carbide.

17. The chamber of claim 16, wherein substrate engaging surfaces of the lift pins are polished to roughness of about 0.2 to 5 μm.

18. The chamber of claim 4, wherein the substrate support is supported by a plurality of substrate support pins, wherein at least one of the plurality of substrate support pins are fabricated from metal-free sintered silicon carbide.

19. The chamber of claim 4, further comprising:
a gas pre-heat ring disposed in the chamber body and surrounding the substrate support, wherein the gas pre-heat ring is fabricated from metal-free sintered silicon carbide.

20. The chamber of claim 4, wherein the substrate support further comprises:
one or more openings formed therethrough and disposed in a substrate support region.

21. The chamber of claim 20, wherein the openings comprise slots.

22. The chamber of claim 20, wherein the openings comprise round holes.

23. The chamber of claim 20, wherein the openings are polygonal.

24. The chamber of claim 20, further comprising between about 1-500 openings.

25. The chamber of claim 20, wherein the openings are radially arranged on the substrate support.

26. The chamber of claim 20, wherein the openings are round holes having a diameter of between about 0.02-0.375 inches.

27. The chamber of claim 20, wherein the openings provide a percent open area over the surface of the substrate support of between about 5 -15 percent.

28. The chamber of claim 4, wherein the substrate support has a thickness of between about 0.04-0.25 inches.

29. The chamber of claim 4, wherein the substrate support has a thickness of between about 0.07-0.12 inches.

30. The chamber of claim 4, wherein the substrate support has a predetermined varying thickness profile.

31. The chamber of claim 30, wherein the thickness profile is varied by a shape of a backside of the substrate support.

32. The chamber of claim 4, further comprising a gap defined between an upper surface of the substrate support and a position corresponding to a backside of a substrate when disposed upon the substrate support.

33. The chamber of claim 32, wherein the gap has a predefined, varying profile.

34. The chamber of claim 33, wherein the profile of the gap is varied by a shape of the upper surface of the substrate support.

35. The chamber of claim 33, wherein the profile of the gap is varied by a shape of a backside of the substrate support.

36. The chamber of claim 33, wherein the profile of the gap includes wider areas corresponding to regions of the substrate desired to be cooler.

37. The chamber of claim 36, wherein the profile of the gap varies by about 0.012 inches.

38. A semiconductor process chamber, comprising:
a chamber body;
a substrate support disposed in the chamber body, wherein the substrate support is fabricated from sintered silicon carbide using non-metallic sintering agents; and
one or more of a pre-heat ring, a lift pin, and a substrate support pin, wherein at least one of the pre-heat ring, the lift pin, and the substrate support pin is fabricated from a solid silicon carbide (SiC) material sintered using non-metallic sintering agents.

39. The reactor of claim 38, wherein the reactor is adapted for performing at least one of deposition processes, etch processes, plasma enhanced deposition and/or etch processes, and thermal processes.

40. The reactor of claim 38, wherein the processes performed by the reactor include epitaxial silicon deposition processes.

41. The reactor of claim 38, wherein the processes performed by the reactor include chemical vapor deposition (CVD) processes.

42. The reactor of claim 38, wherein the processes performed by the reactor include rapid thermal processes (RTPs).

43. The reactor of claim 38, wherein the process kit comprises at least one of a substrate support, a pre-heat ring, a lift pin, and a substrate support pin.
